(19) United States
(12) Patent Application Publication
(10) Pub. No.: US 2023/0411366 A1
(43) Pub. Date: Dec. 21, 2023

(54) SEMICONDUCTOR DEVICE

(71) Applicant: Kioxia Corporation, Tokyo (JP)

(72) Inventor: Masayuki MIURA, Ota Tokyo (JP)

(73) Assignee: Kioxia Corporation, Tokyo (JP)

(21) Appl. No.: 18/336,626

(22) Filed: Jun. 16, 2023

(30) Foreign Application Priority Data
Jun. 17, 2022 (JP) 2022-098129

(51) Int. Cl. H01L 25/16; H01L 23/00; H01L 25/065; H10B 80/00

(52) U.S. Cl. CPC H01L 25/16; H01L 24/48; H01L 24/49; H01L 25/0657; H10B 80/00; H01L 2224/48265; H01L 2224/49109; H01L 2224/48225; H01L 2224/49052; H01L 2225/06562; H01L 2225/0651; H01L 2225/06506

(57) ABSTRACT

A semiconductor device according to the present disclosure includes: a semiconductor chip including a first supply terminal and a second supply terminal; a passive element provided on the semiconductor chip, the passive element including a first electrode, a dielectric provided on the first electrode, and a second electrode provided on the dielectric; a first wiring which electrically connects the first supply terminal and the first electrode to each other; and a second wiring which electrically connects the second supply terminal and the second electrode to each other.

### CROSS-REFERENCE TO RELATED APPLICATION

This application is based upon and claims the benefit of priority from Japanese Patent Application No. 2022-098129, filed on Jun. 17, 2022, the entire contents of which are incorporated herein by reference.

### BACKGROUND OF THE INVENTION

### Field of the Invention

Embodiments described herein relate to a semiconductor device.

### Description of the Related Art

Conventionally, semiconductor devices are known in which a single semiconductor chip or a plurality of semiconductor chips are mounted on a wiring substrate, which is then packaged. In such semiconductor devices, a capacitor may be mounted on the wiring substrate in order to stabilize a power supply.

### BRIEF DESCRIPTION OF THE DRAWINGS

FIG. 1 is a sectional schematic view of a semiconductor device according to a first embodiment;

FIG. 2A is a plan view of a memory chip and a capacitor;

FIG. 2B is a schematic enlarged view of a part of FIG. 2A;

FIG. 3 is a diagram showing a simulation result of an IO skew;

FIG. 4 is a sectional schematic view of a semiconductor device according to a second embodiment;

FIG. 5 is a sectional schematic view of the semiconductor device according to the second embodiment;

FIG. 6 is a sectional schematic view of a semiconductor device according to a third embodiment; and

FIG. 7 is a plan view of the semiconductor device according to the third embodiment.

### DETAILED DESCRIPTION OF THE PREFERRED EMBODIMENTS

Hereinafter, embodiments of the present invention will be described with reference to the accompanying drawings. In order to facilitate understanding of the description, the same constituent elements in the drawings will be denoted by the same reference signs whenever possible and redundant descriptions will not be repeated.

### First Embodiment

Hereinafter, a configuration of a semiconductor device 10 according to the present embodiment will be described. An X axis, a Y axis, and a Z axis may be shown in each drawing. The X axis, the Y axis, and the Z axis form three-dimensional orthogonal coordinates of a right-handed system. Hereinafter, an arrow direction of the X axis may be referred as X-axis forward and a direction opposite to the arrow may be referred to as X-axis rearward. A similar description may also apply to the other axes. Note that Z-axis forward and Z-axis rearward may also be respectively referred to as “upper side” or “upward” and “lower side” or “downward”. In addition, the Z-axis direction may also be referred to as a “stack direction”. Furthermore, planes respectively orthogonal to the X axis, Y axis, or Z axis may be referred to as a YZ plane, a ZX plane, or an XY plane. However, note that these directions and the like are used for the sake of convenience in order to describe relative positional relationships. Therefore, the directions and the like are not intended to define absolute positional relationships.

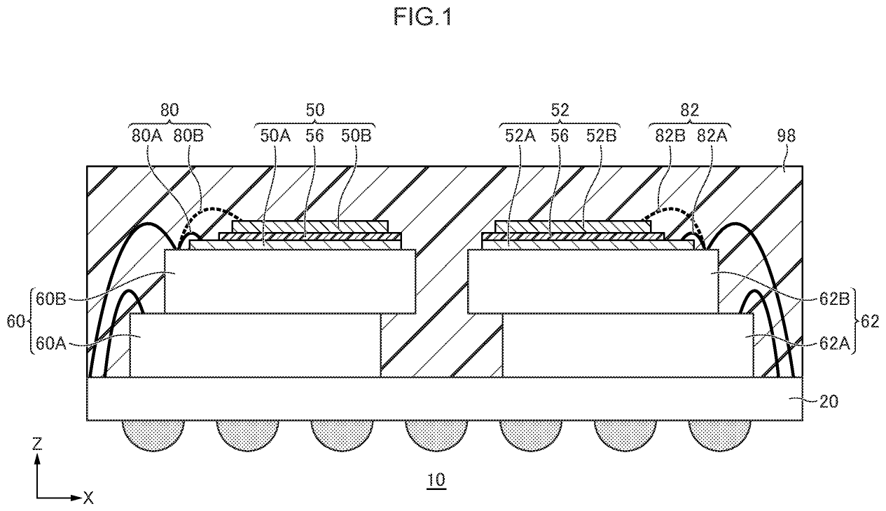

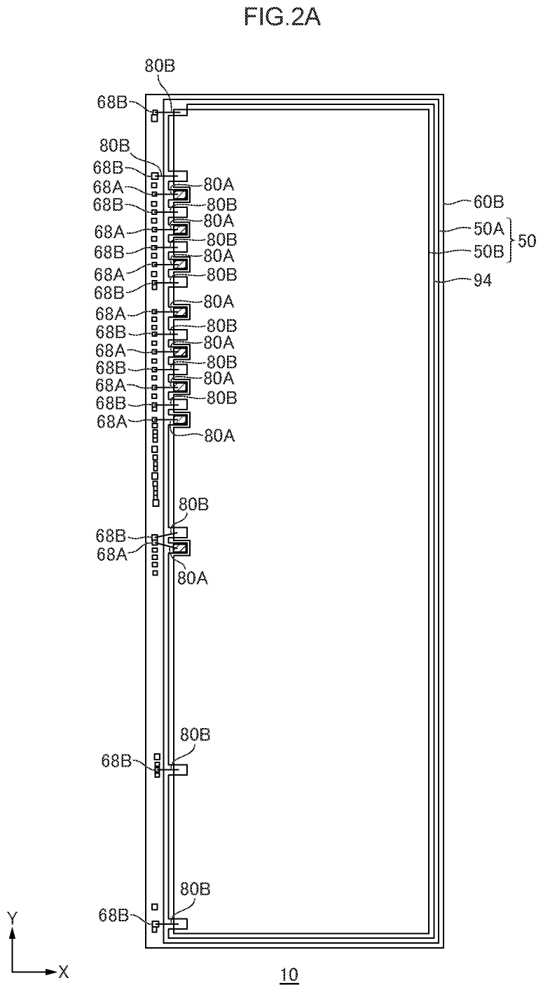

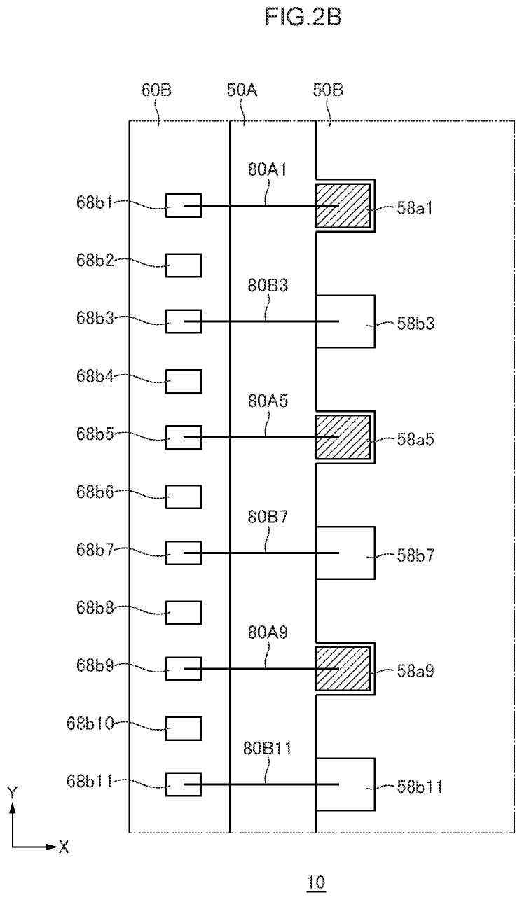

As shown in FIG. 1 and FIG. 2A, the semiconductor device 10 includes: a wiring substrate 20 which functions as an interposer; a plurality of semiconductor memory chips 60 (a semiconductor memory chip 60A and a semiconductor memory chip 60B) stacked on the wiring substrate 20; a capacitor 50 (an example of the “passive element”) provided on the semiconductor memory chip 60B; and a bonding wire 80 (also referred to as a wire 80) including a plurality of first bonding wires 80A (an example of the “first wiring”) which respectively connect a first electrode 50A of the capacitor 50 and a plurality of VCCQ terminals 68A (an example of the “first supply terminal”) included in the semiconductor memory chip 60B and a plurality of second bonding wires 80B (an example of the “second wiring”) which respectively connect a second electrode 50B of the capacitor 50 and a plurality of VSS terminals 68B (an example of the “second supply terminal”) included in the semiconductor memory chip 60B.

In addition, the semiconductor device 10 includes a plurality of semiconductor memory chips 62 (a semiconductor memory chip 62A and a semiconductor memory chip 62B), a capacitor 52, and a bonding wire 82 configured in a similar manner to the semiconductor memory chip 60A, the semiconductor memory chip 60B, the capacitor 50, and the bonding wire 80, and further includes an encapsulating resin 98 (an encapsulating resin layer 98) which encapsulates these elements. As will be described later, the plurality of VCCQ terminals 68A and the plurality of VSS terminals 68B are arranged along the Y-axis direction on the semiconductor memory chip 60A. FIG. 1 shows a schematic cross section corresponding to portions where the VCCQ terminals 68A (not illustrated in FIG. 1) are provided among the semiconductor memory chips 60A, 60B, 62A, and 62B, in which the bonding wire 80A which connects the VCCQ terminals 68A and the first electrode 50A to each other is depicted by a solid line and the bonding wire 80B which connects the VSS terminals 68B (not illustrated in FIG. 1) and the second electrode 50B to each other is depicted by a dotted line. In a similar manner with respect to the semiconductor memory chips 62 and the capacitor 52, in FIG. 1, a bonding wire 82A which connects the VCCQ terminals 68A of the semiconductor memory chip 62B and a first electrode 52A to each other is depicted by a solid line and a bonding wire 82B which connects the VSS terminals 68B and a second electrode 52B to each other is depicted by a dotted line.

The wiring substrate 20 includes a plurality of wiring layers including a front surface layer, a rear surface layer, and an internal wiring layer, a plurality of insulation layers provided between the wiring layers, and, for example, a ball electrode provided on the rear surface layer.

A single semiconductor memory chip or a plurality of semiconductor memory chips are provided on the wiring substrate 20 and, in the present embodiment, two semiconductor memory chips 60A and 60B are stacked on the wiring substrate 20. The semiconductor chips according to the present embodiment are NAND flash memories. However, the semiconductor chips may be an MRAM or other non-volatile semiconductor memory chips, a DRAM or other volatile semiconductor memory chips, or semiconductor chips mounted with a processor such as a logic/interface chip for controlling a semiconductor memory chip. In addition, the semiconductor device 10 may be mounted with a mixture of a plurality of types of semiconductor chips.

As shown in FIG. 2A, the semiconductor memory chip 60B includes a plurality of control signal terminals, a plurality of data signal terminals, and supply terminals as a plurality of terminals. The supply terminals include the plurality of VCCQ terminals 68A for supplying, for example, a voltage of 1.8 V, and the plurality of VSS terminals 68B for supplying, for example, a ground (grounding) potential. In the present embodiment, the plurality of terminals are arranged in the Y-axis direction (an example of the “first direction”) in an upper surface end part (an X-axis direction end part) of the semiconductor memory chip 60B. As shown in FIG. 2A, the plurality of VSS terminals 68B and the plurality of VCCQ terminals 68A are provided separated from each other along the Y-axis direction so as to sandwich terminals of other types between the VSS terminals 68B and the VCCQ terminals 68A. In addition, a thickness of the semiconductor memory chip 60B is, for example, 30.0 μm to 300.0 μm.

Since the semiconductor memory chip 60A has a similar configuration to the semiconductor memory chip a description of the semiconductor memory chip 60A will be omitted. A DAF (Die Attach Film) for bonding the semiconductor memory chip 60A and the semiconductor memory chip 60B to each other is provided between the semiconductor memory chip 60A and the semiconductor memory chip 60B.

The capacitor 50 includes: the first electrode 50A which is provided on the semiconductor memory chip 60B and which extends on an XY plane parallel to an upper surface of the semiconductor memory chip 60B; a dielectric 56 which is provided on the first electrode and which is constituted of an insulator film that extends on an XY plane parallel to the first electrode and the second electrode 50B which is provided on the dielectric 56 and which extends on an XY plane parallel to the dielectric 56. In addition, an upper surface of the second electrode 50B is covered with a protective film 94 with an insulation property.

The second electrode 50B of the capacitor 50 is electrically connected to the plurality of VSS terminals 68B of the semiconductor memory chip 60B by a plurality of the second bonding wires 80B. As shown in FIG. 2A, in a top view, the protective film 94 which covers the upper surface of the second electrode 50B is formed in a comb-teeth shape that is respectively depressed X-axis forward at a plurality of positions opposing the plurality of VSS terminals 68B in the X-axis direction. By forming the protective film 94 in this manner, the upper surface of the second electrode 50B can be exposed at a plurality of positions opposing the plurality of VSS terminals 68B of the semiconductor memory chip 60B in the X-axis direction. A region of the exposed upper surface of the second electrode 50B is provided with a region (pad) for bonding the second bonding wires 80B. Therefore, the second electrode 50B is provided with a plurality of pads arranged in the Y-axis direction so as to correspond to the plurality of VSS terminals 68B arranged in the Y-axis direction.

With such a configuration, the plurality of VSS terminals 68B of the semiconductor memory chip 60B and the second electrode 50B can be electrically connected to each other by the plurality of second bonding wires 80B. In addition, a length of the second bonding wires 80B can be reduced by providing pads at positions opposing the respective VSS terminals 68B.

Furthermore, the first electrode 50A of the capacitor 50 is electrically connected to the plurality of VCCQ terminals 68A of the semiconductor memory chip 60B by a plurality of the first bonding wires 80A. As shown in FIG. 2A, in a top view, the protective film which covers the upper surface of the second electrode and the insulator film which constitutes the dielectric are formed in a comb-teeth shape that is respectively depressed X-axis forward at a plurality of positions opposing the plurality of VCCQ terminals 68A in the X-axis direction. By forming the protective film and the insulator film in this manner, the upper surface of the first electrode 50A can be exposed at a plurality of positions opposing the plurality of VCCQ terminals 68A of the semiconductor memory chip 60B in the X-axis direction. A region of the exposed upper surface of the first electrode 50A is provided with a region (pad) for bonding the first bonding wires 80A. Therefore, the first electrode 50A is provided with a plurality of pads arranged in the Y-axis direction so as to correspond to the plurality of VCCQ terminals 68A arranged in the Y-axis direction.

With such a configuration, the plurality of VCCQ terminals 68A of the semiconductor memory chip 60B and the first electrode 50A can be electrically connected to each other by the plurality of first bonding wires 80A. In addition, a length of the first bonding wires 80A can be reduced.

Connections between the supply terminals (VCCQ terminals and VSS terminals) of the semiconductor memory chip 60B and the electrodes 50A and 50B will be described in detail with reference to FIG. 2B. Note that the protective film 94 is not illustrated in FIG. 2B. As shown in FIG. 2B being an enlargement of a part of FIG. 2A, the semiconductor memory chip 60B is provided with a plurality of pad sections 68b1 to 68b11 which are comparable to a plurality of terminals. In the example illustrated in FIG. 2B, among the plurality of pad sections, the pad sections 68b1, 68b5, and 68b9 correspond to VCCQ terminals. In addition, the pad sections 68b3, 68b7, and 68b11 correspond to VSS terminals. As described earlier, the first electrode 50A is provided on the semiconductor memory chip 60B, the second electrode 50B is provided on the first electrode 50A, parts of the second electrode 50B are depressed and formed in a comb-teeth shape, and parts of the first electrode 50A are exposed upward in the Z-axis direction in FIG. 2B in the depressed portions of the second electrode 50B. As shown in FIG. 2B, the portions of the first electrode 50A which are exposed to the side of the second electrode 50B are pad sections 58a1, 58a5, and 58a9, and the pad sections 58a1, 58a5, and 58a9 are respectively connected to the pad sections 68b1, 68b5, and 68b9 of the semiconductor memory chip 60B by bonding wires 80A1, 80A5, and 80A9. In addition, in the second electrode 50B, pad sections 58b3, 58b7, and 58b11 are provided at positions corresponding in the X-axis direction to the pad sections 68b3, 68b7, and 68b11 of the semiconductor memory chip 60B, and the pad sections 58b3, 58b7, and 58b11 are respectively connected to the pad sections 68b3, 68b7, and 68b11 by bonding wires 80B3, and 80B11.

As shown in FIG. 2A and FIG. 2B, the plurality of control signal terminals and the plurality of data signal terminals of the semiconductor memory chip 60B are not electrically connected to the first electrode 50A and the second electrode 50B of the capacitor 50. Specifically, in FIG. 2B, the pad sections 68b2, 68b4, 68b6, 68b8, and 68b10 other than the pad sections 68b1, 68b3, 68b5, 68b7, 68b9, and 68b11 corresponding to supply terminals correspond to, for example, control signal terminals and data signal terminals and are not electrically connected to both the first electrode 50A and the second electrode 50B.

A thickness in the Z-axis direction of the capacitor according to the present embodiment is configured to be smaller than a thickness of the semiconductor chips (the semiconductor memory chip 60A and the semiconductor memory chip 60B), preferably configured to be equal to or less than half of the thickness of the semiconductor chips, and more preferably configured to be equal to or less than 25% of the thickness of the semiconductor chips. For example, a thickness of the first electrode a thickness of the insulator film, and a thickness of the second electrode 50B of the capacitor 50 according to the present embodiment are, respectively, 2.0 μm, 1.0 μm, and 2.0 μm, in which case the thickness in the Z-axis direction of the capacitor 50 is 5.0 μm.

In this case, the dielectric 56 (insulator film) of the capacitor 50 can be constituted of an STO (SrTiO₃) thin film. STO is superior in terms of low-loss and high-frequency characteristics and has superior bias dependence and temperature dependence. Otherwise, the dielectric 56 may be formed using, for example, various high-permittivity materials such as BTO (BaTiO₃).

The capacitor 50 described above can be manufactured by, for example, forming a metal thin film of around 2.0 μm by sputtering or the like and, after forming an electrode pattern by reactive ion etching (RIE) and forming the first electrode 50A, forming a dielectric film by an aerosol CVD method. Specifically, an STO thin film of around 1.0 μm can be formed under atmospheric pressure by atomizing a sol-gel solution of a precursor of STO, conveying the atomized sol-gel solution with a carrier gas, and spraying the first electrode 50A with the atomized sol-gel solution. Alternatively, for example, the dielectric 56 may be formed by sputtering or the like or may be formed by applying and then heating a sol-gel solution. Next, by forming a metal thin film of around 2.0 μm by sputtering or the like, forming an electrode pattern by reactive ion etching (RIE), and forming the second electrode 50B, the capacitor 50 can be manufactured. The capacitor 50 described above is bonded to the upper surface of the semiconductor memory chip 60B by, for example, a DAF (die attach film). In addition, the first electrode 50A, the dielectric 56, and the second electrode 50B may be directly formed on the semiconductor memory chip 60B.

The bonding wire 80 electrically connects terminals of the semiconductor memory chip 60 and the wiring substrate 20 to each other. For example, the bonding wire 80 respectively electrically connects the plurality of control signal terminals, the plurality of data signal terminals, and the plurality of supply terminals provided on the semiconductor memory chip 60A and the semiconductor memory chip 60B to the wiring pattern formed on the front surface layer of the wiring substrate 20.

Furthermore, as described above, the bonding wire 80 in the present embodiment has a plurality of first bonding wires 80A for respectively connecting the plurality of VCCQ terminals 68A of the semiconductor memory chip 60B to the first electrode 50A of the capacitor 50. In this case, as shown in FIG. 2A, the first bonding wires 80A are connected at one end to the VCCQ terminals 68A and at another end to the first electrode 50A at an advanced position in the X-axis direction from the VCCQ terminals 68A. As a result, in a top view, the first bonding wires 80A extend in the X-axis direction (an example of the “second direction”) which is an extension direction of one side of the semiconductor memory chip 60B and which is orthogonal to the Y-axis direction being an arrangement direction of the plurality of terminals.

Furthermore, as described above, the bonding wire 80 has a plurality of second bonding wires 80B for respectively connecting the plurality of VSS terminals 68B of the semiconductor memory chip 60B to the second electrode 50B of the capacitor 50. Since the second bonding wires 80B are connected at one end to the VSS terminals 68B and at another end to the second electrode 50B at an advanced position in the X-axis direction from the VSS terminals 68B, the second bonding wires 80B extend in a top view in the X-axis direction which is orthogonal to the Y-axis direction.

Since the semiconductor memory chip 62A, the semiconductor memory chip 62B, the capacitor 52, and the bonding wire 82 are configured in a similar manner to the semiconductor memory chip 60A, the semiconductor memory chip 60B, the capacitor 50, and the bonding wire 80, descriptions of the elements will not be repeated.

The semiconductor device configured as described above is mounted to a printed wiring board on which other semiconductor devices or the like including a host interface circuit and a memory controller circuit are mounted, and by electrically connecting the semiconductor device to the memory controller circuit and the like via a ball electrode and a wiring pattern of the printed wiring board, a memory device such as an SSD or a UFS can be constructed.

According to the semiconductor device configured as described above, a power supply can be stabilized since the semiconductor device includes a capacitor.

In addition, compared to a case where a capacitor such as an MLCC is mounted on a wiring substrate, since a region for mounting the MLCC or the like need not be allocated, the wiring substrate can be made relatively smaller.

Furthermore, since a length of wiring for connecting the capacitor and the semiconductor chip to each other can be relatively shortened, an inductance component can be relatively reduced and high-speed operations can be provided. In particular, as illustrated in FIG. 2A, since the first bonding wires 80A (the second bonding wires 80B) are configured to be connected to the first electrode 50A (the second electrode 50B) at positions opposing the VCCQ terminals 68A (the VSS terminals 68B) in a top view, the first bonding wires 80A (the second bonding wires 80B) can be shortened.

In addition, since the plurality of VCCQ terminals 68A (VSS terminals 68B) and the first electrode 50A (the second electrode 50B) are connected by the plurality of first bonding wires 80A (second bonding wires 80B), the inductance component can be further reduced.

Furthermore, since a parallel flat-plate structure is adopted as the capacitor 50 and the thickness of the capacitor 50 is made smaller than the thickness of the semiconductor memory chip 60, a significant increase in the thickness of the entire semiconductor device 10 due to the capacitor 50 can be suppressed.

Note that the first bonding wires 80A can be connected to the VSS terminals 68B and the second bonding wires 80B may be connected to the VCCQ terminals 68A. Furthermore, the first bonding wires 80A or the second bonding wires 80B may be connected to supply terminals of other types.

In addition, the capacitor 50 may have a structure other than a parallel flat-plate structure or a structure partially including a parallel flat-plate structure.

Hereinafter, a result of a simulation of skew (jitter) of semiconductor devices according to comparative examples and the present embodiment will be described. A semiconductor device 100 according to a first comparative example is configured without the capacitor 50 in the configuration shown in FIG. 1. A semiconductor device 200 according to a second comparative example is configured with an MLCC mounted on the wiring substrate 20 instead of the capacitor 50 in the configuration shown in FIG. 1. In addition, a semiconductor device 30 according to another embodiment of the present embodiment is configured with an MLCC mounted on the semiconductor memory chip 60B instead of the capacitor 50 in the configuration shown in FIG. 1.

In such semiconductor devices, a skew (jitter) of a data line was measured by simulation. Specifically, on a data line for transmitting a differential data signal having a voltage (Hi) of VCCQ and a voltage (Low) of VSS, an IO skew (an amount of variability at a position where a pair of the differential data signals cross each other) when transmitting data at a rate of approximately 1 Gbps was measured by a simulation.

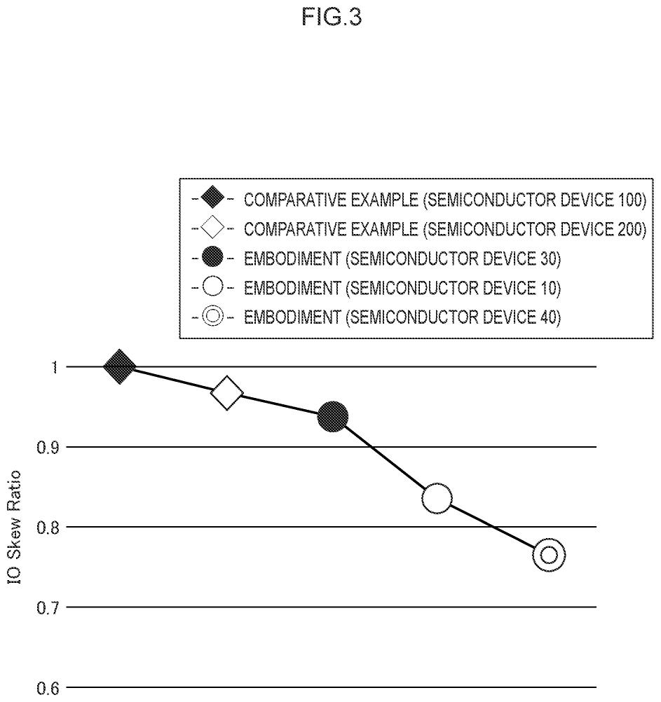

FIG. 3 shows a result of the simulation of IO skew of the semiconductor devices according to the comparative examples and the present embodiment. A result of a simulation of IO skew of a semiconductor device 40 will be described later.

As shown in FIG. 3, when an IO skew in the semiconductor device 100 according to the first comparative example was assumed to be 1, an IO skew in the semiconductor device 200 according to the second comparative example was approximately 0.96. Therefore, mounting a capacitor enables IO skew to be suppressed.

In addition, a ratio of IO skew according to the semiconductor device 30 was approximately 0.94. Therefore, it was revealed that, even when a same capacitor (MLCC) is adopted, IO skew fluctuates due to a mount position. More specifically, by mounting an MLCC on the semiconductor memory chip 60B, IO skew can be suppressed by reducing the length of wiring for connecting the capacitor (MLCC) and the semiconductor chip to each other as compared to the semiconductor device 200 according to the second comparative example.

Furthermore, a ratio of IO skew according to the semiconductor device 10 was approximately 0.83, indicating that IO skew can be reduced by approximately 20% with respect to the IO skew of the semiconductor device 100.

In the semiconductor device 10 according to the present embodiment, the length of wiring to connect electrodes and supply terminals to each other is shorter than that in the semiconductor device 30. In addition, in the semiconductor device 10 according to the present embodiment, the electrodes of the capacitor 50 and the supply terminals are connected to each other by a plurality of bonding wires unlike that in the semiconductor device 30 in which electrodes of an MLCC and supply terminals are connected to each other by a single wiring. As a result of adopting such a configuration, the semiconductor device 10 according to the present embodiment can reduce an inductance component attributable to electrodes of a capacitor and wiring and a power supply stabilizes even during high-speed operations.

### Second Embodiment

Hereinafter, the semiconductor device 40 according to a second embodiment will be described. Note that descriptions of the semiconductor device 40 including same or similar functions or components as the semiconductor device 10 according to the first embodiment will be either omitted or simplified and, rather, differences will be mainly described.

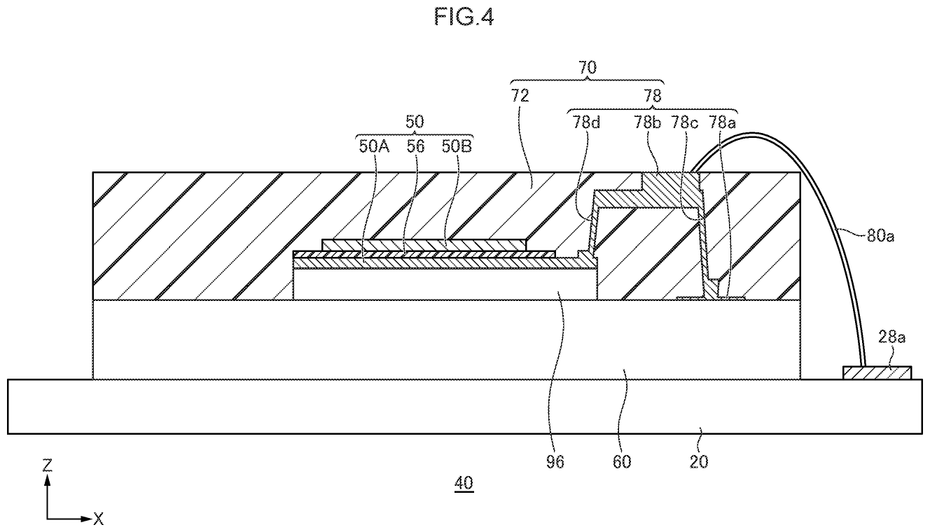

As shown in FIG. 4, the semiconductor device 40 differs from the semiconductor device 10 using the bonding wire 80 in that the semiconductor device 40 includes an RDL 70 (re-distribution layer; hereinafter, an “RDL” may be referred to as a “re-distribution layer”) as wiring for connecting electrodes of the capacitor 50 and supply terminals of a semiconductor chip with each other.

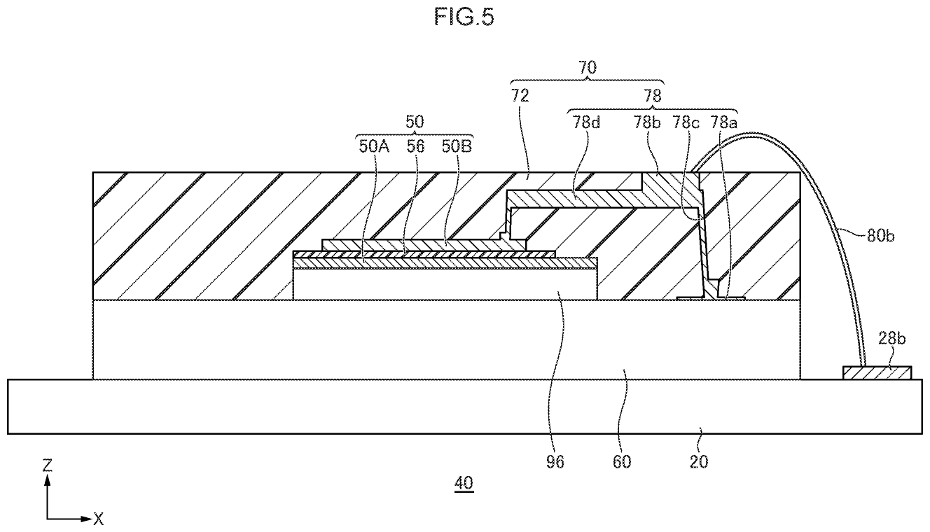

FIG. 4 is a diagram showing a cross section of a portion where a VCCQ terminal of the semiconductor memory chip 60 is connected to the first electrode 50A of the capacitor 50 in the semiconductor device 40. On the other hand, as shown in FIG. 5, in the semiconductor device 40, a VSS terminal of the semiconductor memory chip 60 is connected to the second electrode 50B of the capacitor 50. Note that the semiconductor device 40 is not limited to the configuration illustrated in FIG. 4 and FIG. 5. For example, a configuration may be adopted in which the VCCQ terminal of the semiconductor memory chip 60 is connected to the second electrode 50B of the capacitor 50 and the VSS terminal of the semiconductor memory chip 60 is connected to the first electrode 50A of the capacitor 50. In addition, while the semiconductor device 40 in a case where only one semiconductor memory chip 60 is provided is shown as an example in FIG. 4 and FIG. 5, the semiconductor device 40 may also include a plurality of the semiconductor memory chips 60 in a similar manner to the semiconductor device 10 according to the first embodiment. In the semiconductor device 40 including a plurality of the semiconductor memory chips 60, the plurality of semiconductor memory chips 60 may be stacked in the Z direction in a similar manner to the semiconductor device 10 according to the first embodiment or the plurality of semiconductor memory chips 60 may be provided in parallel in the X direction. Alternatively, the plurality of semiconductor memory chips 60 may be provided in parallel in the X direction and/or the Y direction, and one or two or more semiconductor memory chips 60 may be further stacked in the Z direction on the semiconductor memory chips 60 provided in parallel in the X direction and/or the Y direction.

As shown in FIG. 4, the semiconductor device 40 includes a wiring substrate 20, the semiconductor memory chip 60, the capacitor 50, and the re-distribution layer 70. In the semiconductor device 40, the semiconductor memory chip 60 is provided on the wiring substrate 20 and the capacitor 50 is provided on the semiconductor memory chip 60.

In a similar manner to the capacitor 50 of the semiconductor device 10 according to the first embodiment, the capacitor 50 includes the first electrode the second electrode 50B, and a dielectric 56 provided between the first electrode 50A and the second electrode 50B. In the capacitor 50, the first electrode and the second electrode 50B may be formed so as to have a thickness of, for example, 2.0 μm, and the dielectric 56 may be formed so as to have a thickness of, for example, 1.0 μm. As shown in FIG. 4, the capacitor may be formed on the semiconductor memory chip 60 via, for example, an adhesion layer 96. For example, the adhesion layer 96 may be formed using a film-like adhesive sheet such as a DAF (Die Attach Film). A thickness of the DAF used in the adhesion layer 96 is, for example, 5.0 μm. The DAF used in the adhesion layer 96 may be provided using, for example, a thermosetting resin or a thermoplastic resin.

As shown in FIG. 4, the re-distribution layer 70 is provided on the semiconductor memory chip 60. The re-distribution layer 70 has an insulation layer 72 and a re-distribution structure 78 provided inside the insulation layer 72. As shown in FIG. 4, the re-distribution structure 78 has a first pad section 78a provided on an upper surface side of the semiconductor memory chip 60 in the re-distribution layer 70 (an upper side in the Z-axis direction in FIG. 4) and a second pad section 78b provided on a surface on an opposite side to the semiconductor memory chip 60 in the re-distribution layer 70 (a surface on an upper side in the Z-axis direction of the re-distribution layer 70 in FIG. 4). The first pad section 78a is provided so as to correspond to a terminal on an upper surface of the semiconductor memory chip 60. In the example shown in FIG. 4, the first pad section 78a is provided so as to correspond to a VCCQ terminal on the upper surface of the semiconductor memory chip 60. The second pad section 78b is connected via a first wiring 80a formed of, for example, a bonding wire to a substrate-side pad section 28a provided on the wiring substrate 20. The re-distribution structure 78 further includes a first re-distribution structural section 78c provided so as to connect the first pad section 78a and the second pad section 78b to each other and a second re-distribution structural section 78d provided so that the second pad section 78b connects to the capacitor 50. The second re-distribution structural section 78d is provided so as to be connected to the first electrode 50A of the capacitor 50. According to the configuration described above, the re-distribution structure 78 of the re-distribution layer 70 performs a function of connecting among the wiring substrate 20, the semiconductor memory chip 60, and the capacitor 50 in a similar manner to the bonding wire 80 in the semiconductor device 10 according to the first embodiment. Note that the re-distribution layer 70 can be formed using, for example, a photolithographic technique.

As shown in FIG. 5, a VSS terminal of the semiconductor memory chip 60 is connected to the second electrode 50B of the capacitor 50. In the re-distribution structure 78 of the re-distribution layer 70, the first pad section 78a is provided so as to correspond to a VSS terminal on the upper surface of the semiconductor memory chip 60. The second pad section 78b is connected via a second wiring 80b to a substrate-side pad section 28b provided on the wiring substrate 20. In addition, the second re-distribution structural section 78d is provided so as to be connected to the second electrode 50B of the capacitor 50.

Since supply terminals on the semiconductor memory chip 60 and the electrodes 50A and 50B of the capacitor 50 are connected by the re-distribution layer 70 instead of the bonding wire 80 in the semiconductor device 40, a distance of wiring for connecting the supply terminals on the semiconductor memory chip 60 and the capacitor 50 to each other can be shortened as compared to the semiconductor device 10 according to the first embodiment. Therefore, in the semiconductor device 40, an inductance component attributable to the wiring between the semiconductor memory chip and the capacitor and to the electrodes can be more greatly suppressed.

As shown in FIG. 3, in the semiconductor device 40, IO skew is approximately 0.77 as compared to the semiconductor device 100 according to the first comparative example. The semiconductor device 40 enables IO skew to be even more suppressed than the semiconductor device 10 and the semiconductor device 30 according to other embodiments.

### Third Embodiment

Hereinafter, a semiconductor device 90 according to a third embodiment will be described. Note that descriptions of the semiconductor device 90 including the same or similar functions or components as the semiconductor device 10 according to the first embodiment or the semiconductor device 40 according to the second embodiment will be either omitted or simplified and, rather, differences will be mainly described.

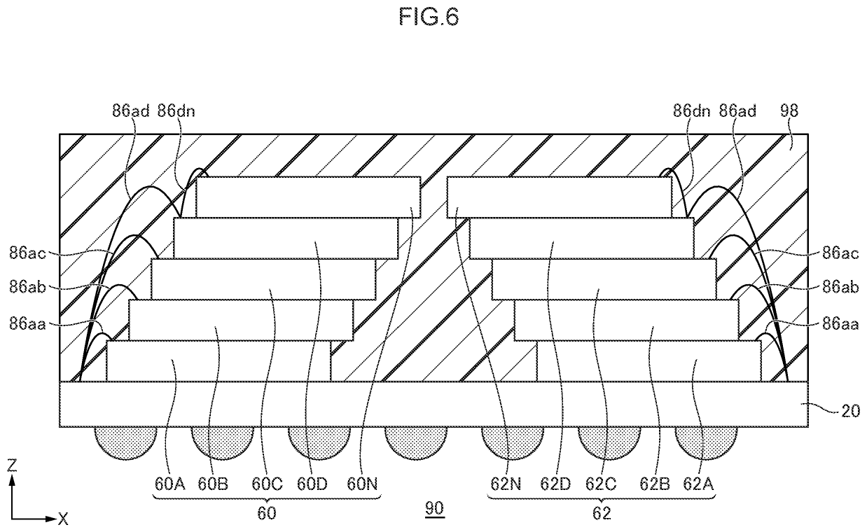

As shown in FIG. 6, the semiconductor device 90 differs from the semiconductor device 10 according to the first embodiment in that a plurality of semiconductor memory chips 60A, 60B, 60C, 60D, and 60N are stacked on a wiring substrate 20 and that the semiconductor memory chip 60N in an uppermost layer (an uppermost layer in the Z-axis direction shown in FIG. 6) provides a similar function to the capacitor 50 in the semiconductor device 10 according to the first embodiment. In other words, in the semiconductor device 90, the semiconductor memory chip 60N in the uppermost layer is configured to function as the capacitor 50. The semiconductor memory chip 60N in the uppermost layer of the semiconductor device 90 is configured to be connected to only a plurality of supply terminals among the plurality of terminals of the other semiconductor memory chips 60 (the semiconductor memory chip 60A, the semiconductor memory chip 60B, the semiconductor memory chip 60C, and the semiconductor memory chip 60D). Therefore, for example, the semiconductor memory chip 60D includes a plurality of control signal terminals, a plurality of data signal terminals, and a plurality of supply terminals as the plurality of terminals and, in the semiconductor device 90, a plurality of supply terminals including a plurality of VCCQ terminals for supplying, for example, a voltage of 1.8 V and a plurality of VSS terminals for supplying, for example, a ground (grounding) potential among the plurality of terminals are connected via, for example, bonding wires 86dn to the semiconductor memory chip 60N in the uppermost layer. As shown in FIG. 6, the semiconductor memory chips 60A, 60B, 60C, and 60D are respectively connected via, for example, bonding wires 86aa, 86ab, 86ac, and 86ad to the plurality of terminals including supply terminals of the substrate 20.

As shown in FIG. 6, the semiconductor device 90 is provided with a plurality of other semiconductor memory chips 62 in parallel in the X direction with the plurality of semiconductor memory chips 60. The plurality of semiconductor memory chips 62 include a semiconductor memory chip 62A, a semiconductor memory chip 62B, a semiconductor memory chip 62C, a semiconductor memory chip 62D, and a semiconductor memory chip 62N in a similar manner to the plurality of semiconductor memory chips 60, and the semiconductor memory chip 62A, the semiconductor memory chip 62B, the semiconductor memory chip 62C, the semiconductor memory chip 62D, and the semiconductor memory chip 62N are stacked in this order. In addition, the semiconductor memory chip 62N in the uppermost layer is connected via the bonding wires 86dn to the supply terminals of the semiconductor memory chip 62D, and the semiconductor memory chips 62A, 62B, 62C, and 62D are respectively connected via, for example, the bonding wires 86aa, 86ab, 86ac, and 86ad to the plurality of terminals including supply terminals of the substrate 20.

As a result of the configuration described above, since bonding wires are only connected to supply terminals among the plurality of terminals with respect to the semiconductor memory chips 60N and 62N in the uppermost layer but bonding wires are also connected to control signal terminals and data signal terminals in addition to the supply terminals among the plurality of terminals with respect to the other semiconductor memory chips 60A to 60D and 62A to 62D, the number of terminals to which bonding wires are connected in the semiconductor memory chips 60N and 62N of the uppermost layer is smaller than the number of terminals to which bonding wires are connected in any of the other semiconductor memory chips 60A to 60D and 62A to 62D. In addition, the semiconductor memory chips 60N and 62N may be semiconductor memory chips manufactured through a same manufacturing process as the semiconductor memory chips 60A to 60D and 62A to 62D and, in such a case, the semiconductor memory chips 60N and 62N may have a same size (dimensions in the X-axis direction, the Y-axis direction, and the Z-axis direction) as the semiconductor memory chips 60A to 60D and 62A to 62D. However, the semiconductor memory chips 60N and 62N may be semiconductor memory chips that are functionally inferior to the semiconductor memory chips 60A to 60D and 62A to 62D. In other words, since only supply signals are input to the semiconductor memory chips 60N and 62N unlike the semiconductor memory chips 60A to 60D and 62A to 62D, semiconductor memory chips that are inferior to the semiconductor memory chips 60A to 60D and 62A to 62D in terms of characteristics can be used as the semiconductor memory chips 60N and 62N insofar as at least supply signals can be input to the semiconductor memory chips. For example, the semiconductor memory chips 60N and 62N may be semiconductor memory chips that do not satisfy predetermined specifications in an inspection step. Even a semiconductor memory chip deemed defective as a semiconductor memory chip can be used as the semiconductor memory chips 60N and 62N insofar as supply signals can be input to the semiconductor memory chip and the semiconductor memory chip can be made to function as a capacitor.

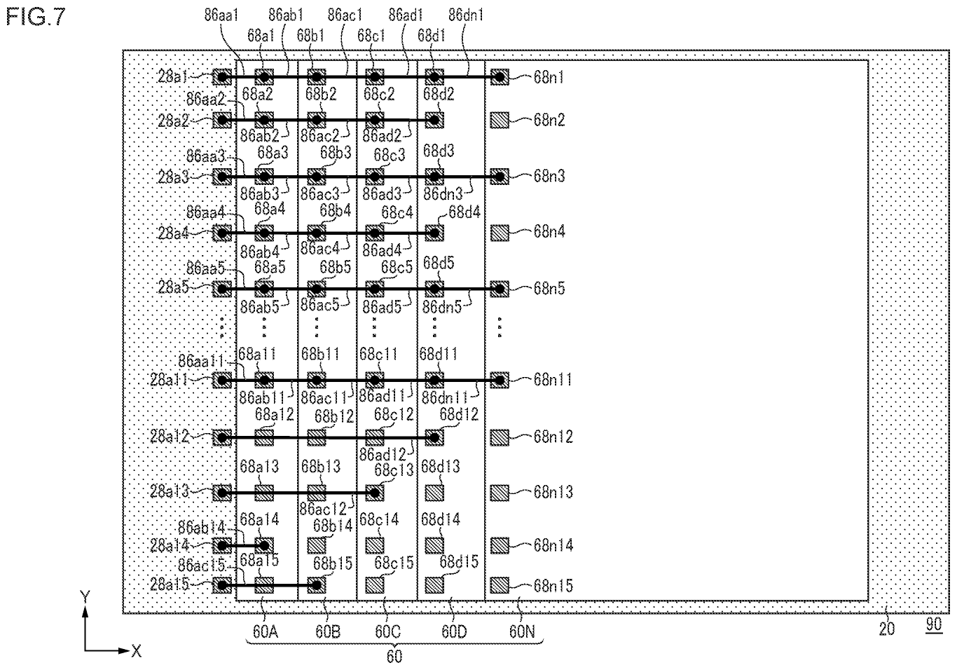

As shown in FIG. 7, the semiconductor device 90 includes the semiconductor memory chip 60A, the semiconductor memory chip 60B, the semiconductor memory chip 60C, the semiconductor memory chip 60D, and the semiconductor memory chip 60N provided on the wiring substrate 20. A plurality of pad sections 28a1 to 28a5 and 28a11 to 28a15 are provided on the wiring substrate Among the plurality of pad sections, for example, the pad sections 28a1, 28a5, and 28a11 are pads for VCCQ and the pad section 28a3 is a pad for VSS. In addition, the pad sections 28a2 and 28a4 are pads for input/output signals. Furthermore, the pad section 28a13 is a pad for a chip address. While detailed descriptions will be omitted, the other pad sections 28a12, 28a14, and 28a15 are pads corresponding to terminals other than supply terminals in a similar manner to the pad sections 28a2, 28a4, and 28a13.

A plurality of pad sections 68a1 to 68a5 and 68a11 to 68a15 are provided on the semiconductor memory chip 60A. In a similar manner, pluralities of pad sections 68b1 to 68b5 and 68b11 to 68b15, 68c1 to 68c5 and 68c11 to 68c15, and 68d1 to 68d5 and 68d11 to 68d15 are respectively provided on the semiconductor memory chips 60C, and 60D and a plurality of pad sections 68n1 to 68n5 and 68n11 to 68n15 are provided on the semiconductor memory chip 60N.

For example, when focusing on the wiring substrate and the semiconductor memory chip 60A, as shown in FIG. 7, the pad section 28a1 is connected by a bonding wire 86aa1 to the pad section 68a1 provided in the X direction of the pad section 28a1. In a similar manner, in the respective relationships between the wiring substrate 20 and the semiconductor memory chips 60B, 60C, and 60D, the pad section 28a1 is respectively connected by the bonding wire 86ab1, the bonding wire 86ac1, and the bonding wire 86ad1 to the pad section 68b1, the pad section 68c1, and the pad section 68d1. Furthermore, in the relationship between the semiconductor memory chip and the semiconductor memory chip 60N, the pad section 68n1 is connected by the bonding wire 86dn1 to the pad section 68d1. According to the above, a voltage VCCQ (for example, 1.8 V) is input from the pad section 28a1 on the wiring substrate 20 to the pad section 68a1 on the semiconductor memory chip 60A, the pad section 68b1 on the semiconductor memory chip 60B, the pad section 68c1 on the semiconductor memory chip 60C, the pad section 68d1 on the semiconductor memory chip 60D, and the pad section 68n1 on the semiconductor memory chip 60N. In a similar manner, with respect to the pad section 28a3, the pad section 28a3 is respectively connected by the bonding wires 86aa3, 86ab3, 86ac3, and 86ad3 to the pad sections 68a3, 68b3, 68c3, and 68d3, and the pad section 68d3 and the pad section 68n3 are connected to each other by the bonding wire 86dn3. According to the above, a voltage VSS (for example, a ground (grounding) potential) is supplied from the pad section 28a3 on the wiring substrate 20 to the pad section 68a3 on the semiconductor memory chip 60A, the pad section 68b3 on the semiconductor memory chip 60B, the pad section 68c3 on the semiconductor memory chip 60C, the pad section 68d3 on the semiconductor memory chip 60D, and the pad section 68n3 on the semiconductor memory chip 60N.

On the other hand, with respect to the pad section 28a2, the pad sections 68a2, 68b2, 68c2, and 68d2 are respectively connected via the bonding wires 86aa2, 86ab2, 86ac2, and 86ad2, and input/output signals are supplied to the pad sections 68a2, 68b2, 68c2, and 68d2. However, none of the pad sections 28a2, 68a2, 68b2, 68c2, and 68d2 are connected to the pad section 68n2 and input/output signals are not supplied to the pad section 68n2. As shown in FIG. 7, in a similar manner, with respect to the pad sections 28a3, 28a5, and 28a11 that correspond to VCCQ and VSS supply terminals on the wiring substrate 20, the pad sections 68n3, 68n5, and 68n11 on the semiconductor memory chip 60N are connected by the bonding wires 86dn3, 86dn5, and 86dn11 from the pad sections 68d3, 68d5, and 68d11 of another semiconductor memory chip 60D. However, the pad sections 28a4, 28a12, 28a13, 28a14, and 28a15 other than the pad sections 28a3, 28a5, and 28a11 that correspond to supply terminals on the wiring substrate 20 are not connected to corresponding pad sections 68n4, 68n12, 68n13, 68n14, and 68n15 of the semiconductor memory chip 60N. Therefore, in the semiconductor device 90, only supply signals are input to the semiconductor memory chip 60N in the uppermost layer and signals other than supply signals are only supplied to one or a plurality of semiconductor memory chips 60A, 60B, 60C, and 60D other than the semiconductor memory chip 60N in the uppermost layer. According to this configuration, in the semiconductor device 90, the semiconductor memory chip 60N in the uppermost layer performs a similar function to the capacitor 50 of the semiconductor device 10 according to the first embodiment. In other words, the semiconductor device 90 can suppress power supply noise such as an inductance component and enables high-speed operations in a similar manner to the semiconductor device 10 according to the first embodiment.

The semiconductor memory chip 60N in the uppermost layer can be provided via, for example, an adhesion layer with respect to an upper surface of the semiconductor memory chip 60D that is directly under the semiconductor memory chip 60N. Therefore, there is no need to separately form the capacitor 50 as in the first embodiment. The DAF (Die Attach Film) described earlier can be used as the adhesion layer.

In addition, while the semiconductor memory chip 60N is provided in the uppermost layer of the plurality of memory chips 60 in the semiconductor device 90 described above, the semiconductor memory chip 60N may be provided at other locations as long as the semiconductor memory chip 60N can function as a capacitor.

Furthermore, the semiconductor device 90 can also be provided with a re-distribution layer in a similar manner to the semiconductor device 40 according to the second embodiment. For example, in the semiconductor device 90, the re-distribution layer 70 may be provided on top of the semiconductor memory chip 60D that is directly under the semiconductor memory chip 60N in the uppermost layer. Providing the re-distribution layer 70 enables a wiring distance to be shortened as compared to, for example, performing wiring using the bonding wire 80 in a similar manner to the semiconductor device 40 according to the second embodiment and, therefore, enables an inductance component to be suppressed.

In addition, while semiconductor devices including one or two semiconductor memory chips have been described as an example in some of the embodiments described above, a semiconductor device according to an embodiment of the present disclosure may include three or more semiconductor memory chips. Furthermore, for example, a semiconductor device according to an embodiment of the present disclosure can be constructed using, for example, four or eight stacked semiconductor memory chips.

Furthermore, while descriptions have been omitted when appropriate in the embodiments described above, the semiconductor devices according to the embodiments described above may be further provided with an encapsulating resin layer 98 so as to cover the semiconductor memory chips 60 and/or the capacitor 50 provided on the wiring substrate 20.

Embodiments have been described above with reference to specific examples. However, it is to be understood that the present disclosure is not limited to the specific examples. Appropriate design modifications of the specific examples made by persons skilled in the art are also included in the scope of the present disclosure insofar as such modifications possess characteristics of the present disclosure. The respective elements included in each specific example described above and arrangements, conditions, shapes, and the like of such elements are not limited to those exemplified and can be modified as appropriate. Combinations of the respective elements included in each specific example described above can be appropriately changed insofar as no technical contradictions arise from such changes.

What is claimed is:

1. A semiconductor device, comprising:
a semiconductor chip including a first supply terminal and a second supply terminal;
a passive element provided on the semiconductor chip, the passive element including a first electrode, a dielectric provided on the first electrode, and a second electrode provided on the dielectric;
a first wiring which electrically connects the first supply terminal and the first electrode to each other; and
a second wiring which electrically connects the second supply terminal and the second electrode to each other.

2. The semiconductor device according to claim 1, wherein a thickness of the passive element is equal to or less than a thickness of the semiconductor chip.

3. The semiconductor device according to claim 1, wherein a thickness of the passive element is equal to or less than half of a thickness of the semiconductor chip.

4. The semiconductor device according to claim 1, wherein
the semiconductor chip includes the first supply terminal in plurality and the second supply terminal in plurality,
wherein the semiconductor device further comprises:
the first wiring in plurality which electrically connect the first supply terminal in plurality and the first electrode to each other; and
the second wiring in plurality which electrically connect the second supply terminal in plurality and the second electrode to each other.

5. The semiconductor device according to claim 4, wherein
the plurality of first supply terminals and the plurality of second supply terminals are arranged in a first direction in a plan view,
the plurality of first wirings include a portion extending in a second direction which is orthogonal to the first direction in a plan view and electrically connect the first supply terminals and the first electrode to each other, and
the plurality of second wirings include a portion extending in the second direction in a plan view and electrically connect the second supply terminals and the second electrode to each other.

6. The semiconductor device according to claim 1, further comprising:
a wiring substrate on which the semiconductor chip is mounted;
a wiring which electrically connects the wiring substrate and the first supply terminal to each other; and
a wiring which electrically connects the wiring substrate and the second supply terminal to each other.

7. The semiconductor device according to claim 1, wherein
the first wiring is a wire, and
the second wiring is a wire.

8. The semiconductor device according to claim 1, further comprising
a re-distribution layer which is provided on the semiconductor chip and in which at least a part of the first wiring and at least a part of the second wiring are formed.

9. A semiconductor device, comprising:
a plurality of wirings; and
a plurality of stacked semiconductor chips, each semiconductor chip including a plurality of terminals, at least one wiring among the plurality of wirings being connected to each terminal, wherein
the number of the plurality of terminals to which the wiring is connected in the semiconductor chip in an uppermost layer is smaller than the number of the plurality of terminals to which the wiring is connected in any of the other semiconductor chips.

10. The semiconductor device according to claim 9, wherein a thickness of the semiconductor chip in the uppermost layer is the same as a thickness of at least one semiconductor chip among the other semiconductor chips.

11. The semiconductor device according to claim 9, wherein a length of at least one side of the semiconductor chip in the uppermost layer is the same as a length of at least one side of at least one semiconductor chip among the other semiconductor chips.

12. The semiconductor device according to claim 9, wherein
the plurality of terminals include a plurality of first supply terminals and a plurality of second supply terminals, and
the plurality of wirings include a plurality of wirings respectively connected to the plurality of first supply terminals of the semiconductor chip in the uppermost layer and a plurality of wirings respectively connected to the plurality of second supply terminals of the semiconductor chip in the uppermost layer.

13. The semiconductor device according to claim 9, wherein the plurality of wirings are wires.
